(19) United States
(12) Patent Application Publication
(10) Pub. No.: US 2025/0346998 A1
(43) Pub. Date: Nov. 13, 2025

(54) GAS DELIVERY NETWORK MODELING

(71) Applicant: Applied Materials, Inc., Santa Clara, CA (US)

(72) Inventors: Youngki CHANG, Santa Clara, CA (US); Kasturi Tulashidas SARANG, San Jose, CA (US); Xiaoxiong YUAN, San Jose, CA (US); Adolph Miller ALLEN, Oakland, CA (US); Karthik RAMANATHAN, Bangalore (IN)

(21) Appl. No.: 18/662,243

(22) Filed: May 13, 2024

(51) Int. Cl. C23C 16/455; C23C 16/458; C23C 16/52

(52) U.S. Cl. CPC C23C 16/45565; C23C 16/458; C23C 16/52

(57) ABSTRACT

A method of substrate processing includes delivering one or more precursors from a precursor delivery system to the processing chamber according to a first precursor delivery system setting (PDSS). A precursor parameter is measured using a sensor disposed within the precursor delivery system. The method also includes determining a second PDSS based upon a comparison between a precursor model parameter value (precursor MPV) and the measured precursor parameter, wherein the second PDSS is selected to achieve the precursor MPV. Thereafter, the one or more precursors are delivered according to the second PDSS.

### FIELD

Embodiments of the present disclosure include gas delivery network modeling in substrate processing systems. More specifically, embodiments of the present disclosure include a method of substrate processing incorporating gas delivery network modeling.

### SUMMARY

In one embodiment, a method of substrate processing includes delivering one or more precursors from a precursor delivery system to the processing chamber according to a first precursor delivery system setting (PDSS). A precursor parameter is measured using a sensor disposed within the precursor delivery system. The method also includes determining a second PDSS based upon a comparison between a precursor model parameter value (precursor MPV) and the measured precursor parameter, wherein the second PDSS is selected to achieve the precursor MPV. Thereafter, the one or more precursors are delivered according to the second PDSS.

In some embodiments, a method of substrate processing includes delivering one or more gases from a gas delivery system to a processing chamber of a substrate processing system according to a first gas delivery system setting (GDSS). A gas parameter is measured using a first sensor disposed within the gas delivery system. The method also includes determining a second GDSS based upon a comparison between a gas model parameter value (gas MPV) and the measured gas parameter, wherein the second GDSS is selected to achieve the gas MPV. Thereafter, the one or more gases is delivered according to the second GDSS.

In some embodiments, a substrate processing system having a processing chamber. The processing chamber includes a substrate support disposed within the processing chamber configured to hold a substrate and a showerhead disposed within the processing chamber. The system also includes a gas delivery system having a first sensor and a precursor delivery system having a second sensor. A controller has a memory that includes computer-readable instructions stored therein. The computer-readable instructions, when executed by a processor of the controller, cause:
(A) delivery of one or more gases from the gas delivery system to the processing chamber according to a first gas delivery system setting (GDSS);
(B) delivery of one or more precursors from the precursor delivery system to the processing chamber according to a first precursor delivery system setting (PDSS);
(C) measurement of a gas parameter using the first sensor disposed within the gas delivery system;
(D) measurement a precursor parameter using the second sensor disposed within the precursor delivery system;
(E) determination of a second GDSS based upon a comparison between a gas model parameter value (gas MPV) and the measured gas parameter, wherein the second GDSS is selected to achieve the gas MPV;
(F) determination of a second PDSS based upon a comparison between a precursor model parameter value (precursor MPV) and the measured precursor parameter, wherein the second PDSS is selected to achieve the precursor MPV;
(G) delivery of the one or more gases according to the second GDSS; and
(H) delivery of the one or more precursors according to the second PDSS.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic top view of a multi-chamber processing system, according to one or more embodiments described herein.

FIG. 2 is a schematic illustration of a deposition chamber, according to one or more embodiments described herein.

FIG. 3 is a schematic view of a resource delivery system according to one or more embodiments described herein.

FIG. 4 is a schematic view of a resource delivery system, according to one or more embodiments described herein.

FIG. 5 is an illustration of a method, according to one or more embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In one embodiment, a method of substrate processing includes delivering one or more gases from a gas delivery system to a processing chamber of a substrate processing system according to a first gas delivery system setting (GDSS) and delivering one or more precursors from a precursor delivery system to the processing chamber according to a first precursor delivery system setting (PDSS). A gas parameter is measured using a first sensor disposed within the gas delivery system, and a precursor parameter is measured using a second sensor disposed within the precursor delivery system. The method also includes determining a second GDSS based upon a comparison between a gas model parameter value (gas MPV) and the measured gas parameter, wherein the second GDSS is selected to achieve the gas MPV; and determining a second PDSS based upon a comparison between a precursor model parameter value (precursor MPV) and the measured precursor parameter, wherein the second PDSS is selected to achieve the precursor MPV. Thereafter, the one or more gases is delivered according to the second GDSS, and the one or more precursors are delivered according to the second PDSS.

### Exemplary Processing System

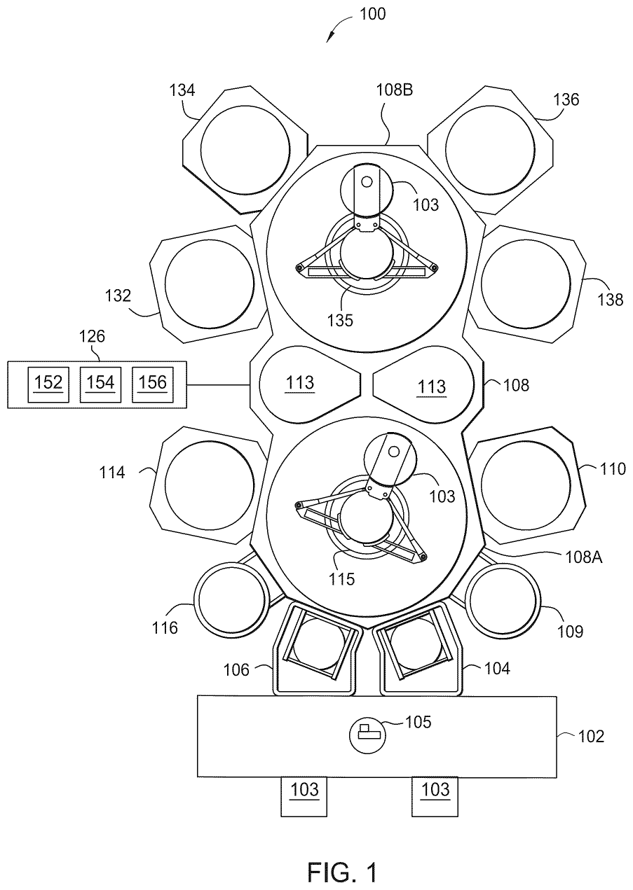

FIG. 1 is a schematic top view of a substrate processing system, according to certain embodiments. The substrate processing system 100 generally includes an equipment front-end module (EFEM) 102 for loading substrates into the substrate processing system 100, a first load lock chamber 104 coupled to the EFEM 102, a transfer chamber 108 coupled to the first load lock chamber 104, and a plurality of other chambers coupled to the transfer chamber 108 as described in detail below. The EFEM 102 generally includes one or more robots 105 that are configured to transfer substrates from the FOUPs 103 to at least one of the first load lock chamber 104 or the second load lock chamber 106. Proceeding counterclockwise around the transfer chamber 108 from the buffer portion 108A of the first load lock chamber 104, the substrate processing system 100 includes a first degas chamber 109, a first pre-clean chamber 110, a first pass-through chamber 112, a second pass-through chamber 113, a second pre-clean chamber 114, a second degas chamber 116 and the second load lock chamber 106. The buffer portion 108A of the transfer chamber 108 includes a first robot 115 that is configured to transfer substrates to each of the load lock chambers 104, 106, the degas chambers 109, 116, the pre-clean chambers 110, 114 and the pass-through chambers 112, 113.

The back-end portion 108B of the transfer chamber 108 includes a second robot 135 that is configured to transfer substrates to each of the pass-through chambers 112, 113 and the processing chambers coupled to the back-end portion 108B of the substrate processing system 100. The processing chambers can include a first processing chamber 132, a second processing chamber 134, a third processing chamber 136, and a fourth processing chamber 138. In general, the processing chambers 132, 134, 136, 138 can include at least one of an atomic layer deposition (ALD) chamber, chemical vapor deposition (CVD) chamber, physical vapor deposition (PVD) chamber, etch chamber, degas chamber, an anneal chamber, and other type of semiconductor substrate processing chamber. In some embodiments, one or more of the processing chambers 132, 134, 136, 138 are a PVD chamber that is configured similar to the processing chamber 200 described below.

The buffer portion 108A and back-end portion 108B of the transfer chamber 108 and each chamber coupled to the transfer chamber 108 are maintained at a vacuum state. As used herein, the term “vacuum” may refer to pressures less than 760 Torr, and will typically be maintained at pressures near 10⁻⁵ Torr (i.e., ˜10⁻³ Pa). However, some high-vacuum systems may operate below near 10⁻⁷ Torr (i.e., ˜10⁻⁵ Pa). In certain embodiments, the vacuum is created using a rough pump and/or a turbomolecular pump coupled to the transfer chamber 108 and to each of the one or more process chambers (e.g., process chambers 109-138). However, other types of vacuum pumps are also contemplated.

A system controller 126, such as a programmable computer, is coupled to the substrate processing system 100 for controlling one or more of the components therein. For example, the system controller 126 may control the operation of the processing chamber 200, which is described further below. In operation, the system controller 126 enables data acquisition and feedback from the respective components to coordinate processing in the substrate processing system 100. The system controller 126 includes a programmable central processing unit (CPU) 152, which is operable with a memory 154 (e.g., non-volatile memory) and support circuits 156. The support circuits 156 (e.g., cache, clock circuits, input/output subsystems, power supplies, etc., and combinations thereof) are conventionally coupled to the CPU 152 and coupled to the various components within the substrate processing system 100.

In some embodiments, the CPU 152 is one of any form of general purpose computer processor used in an industrial setting, such as a programmable logic controller (PLC), for controlling various monitoring system component and sub-processors. The memory 154, coupled to the CPU 152, is non-transitory and is typically one or more of readily available memory such as random access memory (RAM), read only memory (ROM), floppy disk drive, hard disk, or any other form of digital storage, local or remote.

Herein, the memory 154 is in the form of a computer-readable storage media containing instructions (e.g., non-volatile memory), that when executed by the CPU 152, facilitates the operation of the substrate processing system 100. The instructions in the memory 154 are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

### Exemplary Processing Chamber

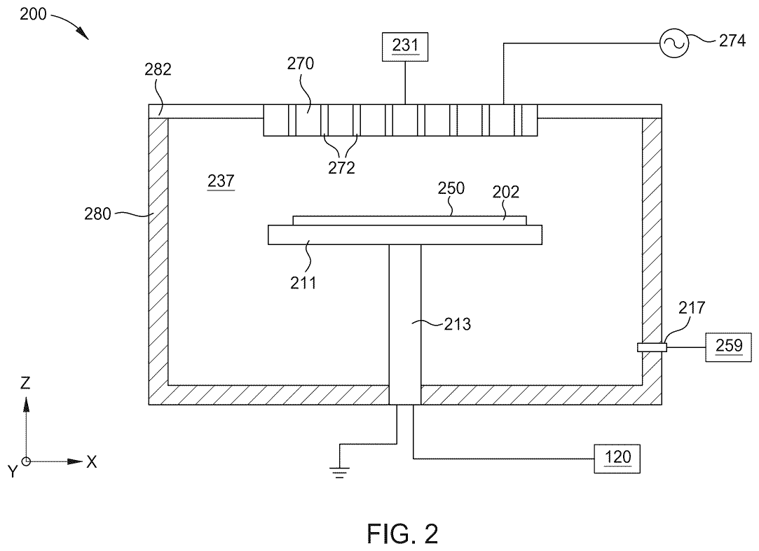

FIG. 2 is a schematic illustration of a second type of processing chamber 200 according to embodiments of the present disclosure. The processing chamber 200 can be any one of the chambers 102-108 within FIG. 1. The processing chamber 200 is a chemical vapor deposition (CVD) chamber and may used as the first chamber within the substrate processing system 100. The processing chamber 200 is utilized to grow a silicide on a substrate, such as the substrate 202.

The processing chamber 200 includes a chamber body 280, a chamber lid 282, a showerhead 270, a substrate support 211, and an exhaust outlet 217. The chamber body 280, the chamber lid 282, and the showerhead 270 define a processing volume 237. The chamber lid 282 is disposed on top of the chamber body 280 with the showerhead 270 either disposed underneath or within the chamber lid 282.

The showerhead 270 may alternatively be a plate stack and is not limited to the showerhead 270 design disclosed herein. The showerhead 270 includes one or more apertures 272 through which a gas is flown into the processing volume 237. The gas may be flown from a gas delivery system 231 into the processing volume 237. The gas delivered to the showerhead 270, the processing volume 237, or both, from the gas delivery system 231 may be an inert gas, a process gas, a purge gas, a precursor, or any combination thereof. The gas delivery system 231 controls the quantity, pressure, temperature, concentration, and flow rate of the gas into the showerhead 270, the processing volume 237, or both. The gas delivery system 231, in some embodiments, may include multiple gas resources 231. For example the gas delivery system 231 may be a precursor delivery system configured to deliver one or more precursors to the showerhead 270, the processing volume 237, or both.

The showerhead 270 is connected to a radio frequency (RF) power source 274. The RF power source 274 is configured to provide a bias between the substrate support 211 and the showerhead 270. Alternatively, the RF power source 274 may be connected to the substrate support 211 and the showerhead 270 may be grounded.

The substrate support 211 is disposed within the processing volume 237 and is configured to support a substrate 202. The substrate support 211 includes a planar upper surface sized to receive the substrate 202. The substrate support 211 is connected to a shaft 213. The shaft 213 extends from the bottom side of the substrate support 211 and is configured to be raised, lowered, or rotated. In some embodiments, the shaft 213 and the substrate support 211 are connected to one or more motors or actuators 120. The shaft 213 and the substrate support 211 are grounded.

The exhaust outlet 217 is connected to both the processing volume 237 and an exhaust pump 259. The exhaust outlet 217 and the exhaust pump 259 remove gases from the processing volume 237. The exhaust outlet 217 is disposed through the chamber body 280.

### Exemplary Resource Delivery System

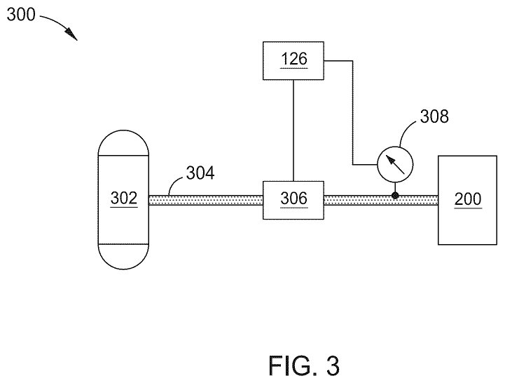

FIG. 3 is a schematic view of a gas delivery system 300 according to one or more embodiments described herein. The gas delivery system 300 may be used as the gas delivery system 231 shown in FIG. 2. According to one embodiment, the gas delivery system 300 includes at least gas one resource 302, one or more gas lines 304, gas delivery equipment 306, and at least a first sensor 308.

The gas resource 302 is coupled to the one or more gas lines 304. The gas line 304 is coupled at a first end, to the gas resource 302, and coupled at a second end, to the processing chamber 200. The gas line 304 include gas delivery equipment 306 disposed along the gas line 304. The first sensor 306 is coupled to the gas line 304 between the gas resource 302 and the processing chamber 200.

The gas resource 302 is configured deliver a gas to the gas line 304. The gas may be of any suitable type, including but not limited to, an inert gas, a process gas, a purge gas, a carrier gas, precursor, or any combination thereof. Example gases include, but are not limited to, argon, hydrogen, helium, ammonia, or combinations thereof. Example precursors include, but are not limited to PDMAT, ((2E)-3-(4-Methoxyphenyl) acrylate) Ruthenium (II)), Ru(CO)₃(1-methyl cyclohexadiene), or combinations thereof. In some embodiments, the gas resource 302 is an ampoule containing a gas.

The gas line 304 is coupled at a first end to the gas resource 302 and coupled at a second end to the processing chamber 200. In operation, the gas line 304 operates to fluidly couple the gas resource 302 to the processing chamber 200. The gas line 304 may be made of any suitable material. The gas line 304 has an inner volume defined by an inner diameter for the passage of the gas. The inner diameter may be constant along the length of the gas line, or may change along the length. The gas line 304 includes the gas delivery equipment 306 disposed along the length of the gas line.

The gas delivery equipment 306 may include, but is not limited to, valves, regulators, pumps, filters, driers, couplers, junctions, fittings, adaptors, or any combination thereof. In operation, the gas delivery equipment 306 allows for the transport and control of the gas flowing from the gas resource 302 to the processing chamber 200. The gas delivery equipment 306 is electrically coupled to the controller 126.

The gas delivery system 300 includes at least a first sensor 308. The first sensor 308 is coupled to the gas line 304 between the gas resource 302 and the processing chamber 200. In some embodiments, the first sensor 308 may be a component of the processing chamber 200. The first sensor 308 is electrically coupled to the controller 126. The first sensor 308 may be of any suitable type, including, but not limited to, a pressure sensor, a temperature sensor, a flow sensor, a concentration sensor, or any combination thereof.

In some embodiments, a plurality of gas delivery systems 300 are utilized. Each gas delivery system 300 is coupled to a gas line 304, and each gas line 304 is coupled to the processing chamber 200. Each gas delivery system 300 has at least a first sensor 308 coupled to each gas line 304 between each gas resource 302 and the processing chamber 200. In some embodiments, the gas delivery system 300 is configured to be a precursor delivery system to deliver one or more precursors to the processing volume 237 of the processing chamber 200.

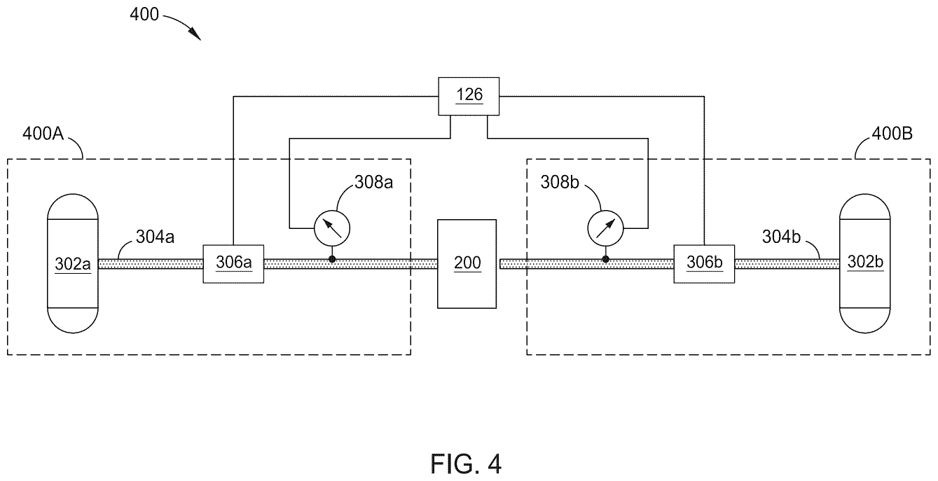

FIG. 4 is a schematic view of a resource delivery system 400 according to one or more embodiments described herein. According to one embodiment, the resource delivery system 400 includes at least one gas delivery system 400A and at least one precursor delivery system 400B. Similar to the gas delivery system 300 described above, the gas delivery system 400A includes at least gas resource 302A, one or more gas lines 304A, gas delivery equipment 306A, and at least a first sensor 308A. In some embodiments, the gas resource 302A is an ampoule containing a gas and/or a liquid.

According to one embodiment, the precursor delivery system 400B includes at least one precursor resource 302B, one or more precursor lines 304B, precursor delivery equipment 306B, and at least a second sensor 308B.

The precursor resource 302B is coupled to the one or more precursor lines 304B. The precursor line 304B is coupled at a first end, to the precursor resource 302B, and coupled at a second end, to the processing chamber 200. The precursor line 304B include the precursor delivery equipment 306B disposed along the precursor line 304B. The second sensor 306B is coupled to the precursor line 304B between the precursor resource 302B and the processing chamber 200.

The precursor delivery system 400B includes a precursor resource 302B. The precursor resource 302B is configured to deliver a precursor to the precursor line 304B. The precursor may be of any suitable type, including but not limited to, an inert precursor, a process precursor, a purge precursor, a carrier precursor, precursor, or any combination thereof. Example precursors include, but are not limited to PDMAT, ((2E)-3-(4-Methoxyphenyl) acrylate) Ruthenium (II)), Ru(CO)₃(1-methyl cyclohexadiene), or combinations thereof. In some embodiments, the precursor resource 302B is an ampoule containing one or more of the precursors.

In operation, the precursor line 304B fluidly couples the precursor resource 302B to the processing chamber 200. The precursor line 304B may be made of any suitable material. The precursor line 304B has an inner volume defined by an inner diameter for the passage of the precursor. The inner diameter may be constant along the length of the precursor line, or may change along the length. The precursor line 304B includes precursor delivery equipment 306B disposed along the length of the precursor line 304B.

The precursor delivery equipment 306B may include, but is not limited to, valves, regulators, pumps, filters, driers, couplers, junctions, fittings, adaptors, or any combination thereof. In operation, the precursor delivery equipment 306B allows for the transport and control of the precursor flowing from the precursor resource 302B to the processing chamber 200. The precursor delivery equipment 306B is electrically coupled to the controller 126.

The precursor delivery system 400B includes at least a second sensor 308B. The second sensor 308B is coupled to the precursor line 304 between the precursor resource 302 and the processing chamber 200. In some embodiments, the second sensor 308B may be a component of the processing chamber 200. The second sensor 308B is electrically coupled to the controller 126. The second sensor 308B may be of any suitable type, including, but not limited to, a pressure sensor, a temperature sensor, a flow sensor, a concentration sensor, or any combination thereof.

### Example Process Sequence

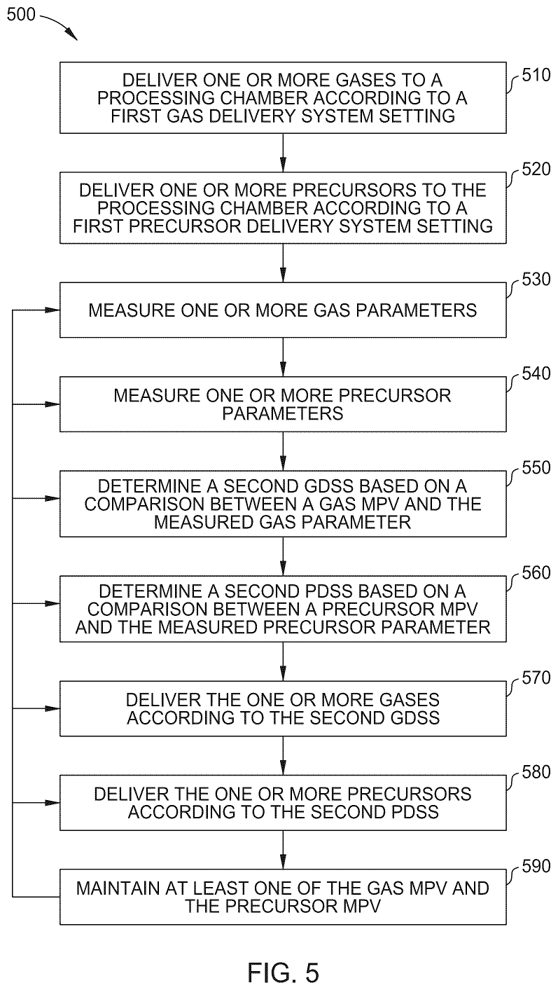

FIG. 5 is an illustration of a method 500, according to one or more embodiments described herein. While the various operations in method 500 are presented and described sequentially, one of ordinary skill in the art will appreciate that some or all of the operations may be executed in different order, may be combined or omitted, and some or all of the operations may be executed in parallel. The operations may be performed actively or passively. The method may be repeated or expanded to support multiple components or multiple users within a field environment. Accordingly, the scope should not be considered limited to the specific arrangement of operations shown in FIG. 5, or described below.

At operation 510, the method 500 includes delivering, from at least one gas delivery system, one or more gases to a processing volume of a processing chamber of a substrate processing system. In one embodiment, the gas is delivered to the processing volume by flowing the one or more gases from a gas resource through at least a first line to a showerhead. The one or more gases can be delivered according to a current (“first”) gas delivery system setting. Exemplary gas delivery system settings include a gas flow rate, a gas temperature (e.g., at the ampoule), a gas concentration, a gas valve opening time, a gas pressure, or any combination thereof.

At operation 520, the method 500 includes delivering, from at least one precursor delivery system, one or more precursors to the processing volume. In one embodiment, the precursor is delivered to the processing volume by flowing the one or more precursors from a precursor resource through at least a second line to the showerhead. The one or more precursors can be delivered according to a current (“first”) gas delivery system setting. In one example, the one or more precursors is delivered from an ampoule through at least a second line to the showerhead. Exemplary precursor delivery system settings include a precursor flow rate, a precursor temperature (e.g., at the ampoule), a precursor concentration, a precursor valve opening time, a precursor pressure, or any combination thereof.

At operation 530, the method 500 includes measuring one or more gas parameters using at least a first sensor disposed within the gas delivery system. In some embodiments, the gas parameter is measured in real time. Exemplary gas parameters measured by the first sensor include a gas pressure, a gas flow rate, a gas temperature, a gas concentration, or any combination thereof. In one example, the first sensor is a pressure sensor for measuring a gas pressure in the first delivery line.

At operation 540, the method 500 includes measuring one or more precursor parameters using at least a second sensor disposed within the precursor delivery system. In some embodiments, the precursor parameter is measured in real time. Exemplary precursor parameters measured by the second sensor include a precursor pressure, a precursor flow rate, a precursor temperature, a precursor concentration, or any combination thereof. In one example, the second sensor is a pressure sensor for measuring a precursor pressure in the second delivery line. It is contemplated operations 540 may be performed before, after, or simultaneous with operation 530.

At operation 550, the method 500 includes determining a second gas delivery system setting (GDSS) based upon a comparison between the measured gas parameter and at least one predetermined gas model parameter value (gas MPV). The second gas delivery system setting is selected to achieve the predetermined gas model parameter value. Exemplary gas delivery system settings include a gas pressure, a gas flow rate, a gas temperature, a gas concentration, a gas valve opening time, or any combination thereof. In some embodiments, the MPV is determined using a simulation platform for modeling of mechanical and fluid systems, such as a gas delivery system for a semiconductor processing system. An exemplary simulation platform is the Amesim™ software, which is commercially available. The gas MPV can be based on a configuration of the gas delivery system and the at least one precursor delivery system. For example, the simulation platform is used to predict the MPV for the gas delivery system. In some embodiments, one or more of the gas MPV are stored in a memory of a controller, such as controller 126. In some examples, the first GDSS, the second GDSS, or both are determined in real time.

In some embodiments, the configuration of the gas delivery system includes at least one gas resource and one or more gas lines having an inlet and an outlet. The inlet is coupled to the at least one gas resource, and the outlet is coupled to the processing chamber. The gas delivery system also includes at least a first sensor coupled to the gas delivery system and gas delivery equipment. In some examples, the configuration of the processing chamber includes a processing volume and a substrate support disposed within the processing volume and configured to hold a substrate. The processing chamber also includes a showerhead disposed within the processing volume. The showerhead has one or more apertures configured to flow the one or more gases, the one or more precursors, or both, to the processing volume.

In some examples, the measured gas parameter is gas pressure, and the measured gas pressure is used to determine the second gas delivery system settings such as gas flow rate, gas temperature, gas valve opening time, or combinations thereof. For example, if the measured gas pressure is below the model gas pressure, then it may be an indication too much gas is being delivered. In response, the second GDSS can be selected to decrease the amount of gas delivered. For example, the gas flow rate can be decreased, the gas temperature at the ampoule can be decreased, the valve opening time can be decreased, or combinations thereof.

At operation 560, a second precursor delivery system setting (PDSS) is determined based upon a comparison between the measured precursor parameter and at least one predetermined precursor model parameter value. The second precursor delivery system setting is selected to achieve the predetermined precursor model parameter value. Exemplary precursor delivery system settings include a precursor pressure, a precursor flow rate, a precursor temperature, a precursor concentration, a precursor valve opening time, or any combination thereof. In some embodiments, the MPV is determined using a simulation platform for modeling of mechanical and fluid systems, such as a precursor delivery system for a semiconductor processing system. An exemplary simulation platform is the Amesim™ software, which is commercially available. The precursor MPV can be based on a configuration of the gas delivery system and the at least one precursor delivery system. For example, the simulation platform is used to predict the MPV for the precursor delivery system. In some embodiments, one or more of the precursor MPV are stored in a memory of a controller, such as controller 126. In some examples, the first PDSS, the second PDSS, or both are determined in real time.

In some embodiments, the configuration of the precursor deliver system includes at least one precursor resource and one or more gas lines having an inlet and an outlet. The inlet is coupled to the at least one precursor resource, and the outlet is coupled to the processing chamber. The precursor delivery system also includes at least a second sensor coupled to the precursor delivery system and the precursor delivery equipment.

In some examples, the measured precursor parameter is precursor pressure, and the measured precursor pressure is used to determine the second precursor delivery system settings such as precursor flow rate, precursor temperature, a precursor valve opening time, or combinations thereof. For example, if the measured precursor pressure is below the model precursor pressure, then it may be an indication too much precursor is being delivered. In response, the second PDSS can be selected to decrease the amount of precursor delivered. For example, the precursor flow rate can be decreased, the precursor temperature at the ampoule can be decreased, the valve opening time can be decreased, or combinations thereof.

At operation 570, the current GDSS is adjusted to the second GDSS to achieve the gas MPV based on the comparison performed in operation 550. In this respect, the one or more gases will be delivered in accordance with the second GDSS. In one example, if the gas MPV is not reached using the second GDSS, operations 530 and 550 can be repeated to determine and select another GDSS (e.g., third GDSS). In some examples, the GDSS is adjusted in real time.

At operation 580, the current PDSS is adjusted to the second PDSS to achieve the precursor MPV based on the comparison performed in operation 560. In this respect, the one or more precursors will be delivered in accordance with the second PDSS. In one example, if the precursor MPV is not reached using the second PDSS, operations 540 and 560 can be repeated to determine and select another PDSS (e.g., third PDSS). In some examples, the PDSS is adjusted in real time. In some examples, the method includes performing operations 530, 550, and 570 without performing operations 540, 560, and 580. In some examples, the method includes performing operations 540, 560, and 580 without performing operations 530, 550, and 570.

At operation 590, the method 500 includes maintaining at least one of the gas MPV by controlling the one or more GDSS, the precursor MPV by controlling the one or more PDSS, or both. In one example, the gas MPV can be maintained by repeating operations 530, 550, and 570. The precursor MPV can be maintained by repeating operations 540, 560, and 580. In some examples, operation 590 is optional.

In some embodiments, the substrate processing system may require a hardware change. The hardware change may include changes due to replacement, modification, failure, or pending failure, of the hardware of the at least one gas delivery system, the at least one precursor delivery system, a processing chamber hardware configuration, or any combination thereof.

In one embodiment, the substrate processing system may be configured to detect a hardware change. In one example, the hardware change can be detected by determining a difference between the gas MPV and one or more measured gas parameters, a difference between the precursor MPV and one or more precursor parameters, or both. The difference is then compared to a predetermined threshold that indicates new hardware has been installed. When the difference exceeds the threshold, a warning is sent to an interface of the substrate processing system.

In one example, the hardware change may involve a change in the length of the second (precursor) delivery line. The precursor pressure in the second delivery line can be measured and compared to the model precursor pressure value. For example, if the measured precursor pressure is above the model precursor pressure value, then it may be an indication that not enough precursor is being delivered. In response (e.g., to the warning), the PDSS can be selected to increase the amount of precursor delivered. For example, the precursor flow rate can be increased, the precursor temperature at the ampoule can be increased, the valve opening time can be increased, or any combination thereof.

In one embodiment, the substrate processing system may be configured to detect a failure or a pending failure. In one example, the failure can be detected by requesting (e.g., measure) a first pressure from the first sensor at a first time and requesting a second pressure from the first sensor at a second time. The difference between the first pressure and the second pressure is calculated. If the difference exceed a threshold, then it's an indication of a failure or pending failure. A warning is sent to an interface of the substrate processing system. In one example, the threshold is larger than the typical variations in the pressure encountered during operation. In some examples, the difference in pressures is an indication that the showerhead is at least partially clogged. The precursor delivery system settings can be adjusted to increase the amount of precursor being delivered to counter the at least partially clogged showerhead.

In another example, the pressures measured are the pressures of the precursor. In this instance, the difference in pressures can be used to determine the amount of precursor remaining within a precursor resource. For example, if the first measured pressure is more than the measured second pressure, then it may be indication the precursor remaining in the precursor resource (e.g., ampoule) is below a threshold amount. In turn, the amount of precursor being delivered may be insufficient. In response, the precursor delivery system settings can be adjusted to increase the amount of precursor being delivered. For example, the precursor flow rate can be increased, the precursor temperature at the resource (e.g., ampoule) can be increased, the valve opening time can be increased, or any combination thereof.

As used herein, “a CPU,” “a processor,” “at least one processor” or “one or more processors” generally refers to a single processor configured to perform one or multiple operations or multiple processors configured to collectively perform one or more operations. In the case of multiple processors, performance the one or more operations could be divided amongst different processors, though one processor may perform multiple operations, and multiple processors could collectively perform a single operation.

Similarly, “a memory,” “at least one memory” or “one or more memories” generally refers to a single memory configured to store data and/or computer-readable instructions, multiple memories configured to collectively store computer-readable data and/or computer-readable instructions, either a transitory or non-transitory form. Illustrative non-transitory computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory devices, e.g., solid state drives (SSD)) on which information may be permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure. In some embodiments, the methods set forth herein, or portions thereof, are performed by one or more application specific integrated circuits (ASICs), field-programmable gate arrays (FPGAs), or other types of hardware implementations. In some other embodiments, the substrate processing and/or handling methods set forth herein are performed by a combination of software routines, ASIC(s), FPGAs and, or, other types of hardware implementations.

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations. It should be understood that the described program components and systems may generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a nonspecific plane of reference. This non-specific plane of reference may be vertical, horizontal, or other angular orientation.

The singular forms “a,” “an,” and “the” include plural referents, unless the context clearly dictates otherwise. Within a claim, reference to an element in the singular is not intended to mean “one and only one” unless specifically so stated, but rather “one or more.” Unless specifically stated otherwise, the term “some” refers to one or more.

Embodiments of the present disclosure may suitably “comprise”, “consist” or “consist essentially of” the limiting features disclosed, and may be practiced in the absence of a limiting feature not disclosed. As used here and in the appended claims, the words “comprise,” “has,” and “include” and all grammatical variations thereof are each intended to have an open, non-limiting meaning that does not exclude additional elements, processes, or steps.

“Optional” and “optionally” means that the subsequently described material, event, or circumstance may or may not be present or occur. The description includes instances where the material, event, or circumstance occurs and instances where it does not occur.

As used, the term “determining” encompasses a wide variety of actions. For example, “determining” may include calculating, computing, processing, deriving, investigating, looking up, for example, looking up in a table, a database or another data structure, and ascertaining. Also, “determining” may include receiving, for example, receiving information, and accessing, for example, accessing data in a memory. Also, “determining” may include resolving, selecting, choosing, and establishing.

When the word “approximately” or “about” are used, this term may mean that there may be a variance in value of up to +10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. The following claims are not intended to be limited to the embodiments provided but rather are to be accorded the full scope consistent with the language of the claims.

What is claimed is:

1. A method of substrate processing, comprising:
(A) delivering one or more gases from a gas delivery system to a processing chamber of a substrate processing system according to a first gas delivery system setting (GDSS);
(B) delivering one or more precursors from a precursor delivery system to the processing chamber according to a first precursor delivery system setting (PDSS);
(C) measuring a gas parameter using a first sensor disposed within the gas delivery system;
(D) measuring a precursor parameter using a second sensor disposed within the precursor delivery system;
(E) determining a second GDSS based upon a comparison between a gas model parameter value (“gas MPV”) and the measured gas parameter, wherein the second GDSS is selected to achieve the gas MPV;
(F) determining a second PDSS based upon a comparison between a precursor model parameter value (“precursor MPV”) and the measured precursor parameter, wherein the second PDSS is selected to achieve the precursor MPV;
(G) delivering the one or more gases according to the second GDSS; and
(H) delivering the one or more precursors according to the second PDSS.

2. The method of claim 1, further comprising repeating processes (A) to (K) so the measured gas parameter reaches the gas MPV, the measured precursor parameter reaches the precursor MPV, or both.

3. The method of claim 1, wherein processes (A) to (K) are performed in real time.

4. The method of claim 1, wherein the delivering the one or more gases comprises flowing the one or more gases from a gas resource through at least a first line to a showerhead.

5. The method of claim 1, wherein the delivering the one or more precursors comprises flowing the one or more precursors from a precursor resource through at least a first line to a showerhead.

6. The method of claim 1, wherein the gas parameter is selected from a gas pressure, a gas concentration, or any combination thereof, and
wherein the precursor parameter is selected from a precursor pressure, a precursor concentration, or any combination thereof.

7. The method of claim 1, wherein the first gas delivery system setting comprises a gas flow rate, a gas temperature, a gas valve opening time, or any combination thereof, and
wherein the first precursor delivery system setting comprises a precursor pressure, a precursor flow rate, a precursor temperature, a precursor valve opening time, or any combination thereof.

8. The method of claim 1, wherein at least one of the gas MPV and the precursor MPV is based on a configuration of the gas delivery system, the precursor delivery system, or both.

9. The method of claim 8, wherein the configuration of the gas delivery system comprises:
at least one gas resource;
one or more gas lines having an inlet and an outlet, wherein the inlet is coupled to the at least one gas resource, and the outlet is coupled to the processing chamber;
the first sensor coupled to the gas delivery system; and
a gas delivery equipment.

10. The method of claim 8, wherein the configuration of the precursor delivery system comprises:
at least one precursor resource;
one or more gas lines having an inlet and an outlet, wherein the inlet is coupled to the at least one precursor resource, and the outlet is coupled to the processing chamber;
the second sensor coupled to the precursor delivery system; and
a precursor delivery equipment.

11. The method of claim 8, wherein at least one of the gas MPV and the precursor MPV is additionally based on a configuration of the processing chamber, the configuration of the processing chamber comprising:
a processing volume;
a substrate support disposed within the processing volume configured to hold a substrate; and
a showerhead disposed within the processing volume, wherein the showerhead includes one or more apertures configured to flow the one or more gases, the one or more precursors, or both, to the processing volume.

12. The method of claim 1, further comprising:
detecting a hardware change by determining a difference between the gas MPV and the one or more gas parameters, the precursor MPV and the one or more precursor parameters, or both;
determining that the difference exceeds a threshold; and
sending a warning to an interface of the substrate processing system.

13. The method of claim 1, further comprising:
measuring a first pressure from the first sensor at a first time;
measuring a second pressure from the first sensor at a second time;
calculating a difference between the first pressure and the second pressure; and
sending a warning to an interface of the substrate processing system if the difference exceeds a threshold.

14. The method of claim 1, further comprising:
measuring a first pressure from the first sensor at a first time;
measuring a first pressure from the first sensor at a second time;
calculating a difference between the first pressure and the second pressure;
determining that a showerhead is at least partially clogged based on the difference; and
sending a warning to an interface of the substrate processing system.

15. The method of claim 1, further comprising:
measuring a first pressure from the first sensor at a first time;
measuring a first pressure from the first sensor at a second time;
calculating a difference between the first pressure and the second pressure;
determining an amount of precursor remaining within a precursor resource based upon the difference; and
sending a warning to an interface of the substrate processing system if the difference exceeds a threshold.

16. A substrate processing system comprising:
a processing chamber having:
a substrate support disposed within the processing chamber configured to hold a substrate; and
a showerhead disposed within the processing chamber;
a gas delivery system having a first sensor:
a precursor delivery system having a second sensor; and
a controller having a memory that includes computer-readable instructions stored therein, and the computer-readable instructions, when executed by a processor of the controller, cause:
(A) delivery of one or more gases from the gas delivery system to the processing chamber according to a first gas delivery system setting (GDSS);
(B) delivery of one or more precursors from the precursor delivery system to the processing chamber according to a first precursor delivery system setting (PDSS);
(C) measurement of a gas parameter using the first sensor disposed within the gas delivery system;
(D) measurement a precursor parameter using the second sensor disposed within the precursor delivery system;
(E) determination of a second GDSS based upon a comparison between a gas model parameter value (gas MPV) and the measured gas parameter, wherein the second GDSS is selected to achieve the gas MPV;
(F) determination of a second PDSS based upon a comparison between a precursor model parameter value (precursor MPV) and the measured precursor parameter, wherein the second PDSS is selected to achieve the precursor MPV;
(G) delivery of the one or more gases according to the second GDSS; and
(H) delivery of the one or more precursors according to the second PDSS.

17. The substrate processing system of claim 16, wherein the instructions further cause:
detection a hardware change by determining a difference between the gas MPV and the one or more gas parameters, the precursor MPV and the one or more precursor parameters, or both;
determination that the difference exceeds a threshold; and
delivery of a warning to an interface of the substrate processing system.

18. The substrate processing system of claim 16, wherein the instructions further cause:
calculation of a difference between the gas model parameter value (gas MPV) and the measured gas parameter;
determination that a showerhead is at least partially clogged based on the difference; and
delivery of a warning to an interface of the substrate processing system.

19. The substrate processing system of claim 16,
wherein the gas parameter is selected from a gas pressure, a gas concentration, or any combination thereof, and
wherein the precursor parameter is selected from a precursor pressure, a precursor concentration, or any combination thereof.

20. The substrate processing system of claim 16,
wherein the first gas delivery system setting comprises a gas flow rate, a gas temperature, a gas valve opening time, or any combination thereof, and
wherein the first precursor delivery system setting comprises a precursor pressure, a precursor flow rate, a precursor temperature, a precursor valve opening time, or any combination thereof.
